(19) United States
(12) Patent Application Publication
(10) Pub. No.: US 2025/0092524 A1
(43) Pub. Date: Mar. 20, 2025

(54) SUBSTRATE PROCESSING APPARATUS, CONTROL SYSTEM, AND CONTROL METHOD

(71) Applicant: Tokyo Electron Limited, Tokyo (JP)

(72) Inventor: Masatoshi SATO, Nirasaki City (JP)

(21) Appl. No.: 18/964,874

(22) Filed: Dec. 2, 2024

Related U.S. Application Data
(63) Continuation of application No. PCT/JP2023/019724, filed on May 26, 2023.

(30) Foreign Application Priority Data
Jun. 9, 2022 (JP) 2022-093974

(51) Int. Cl. C23C 16/52; C23C 16/455; G06F 1/08

(52) U.S. Cl. CPC C23C 16/52; G06F 1/08; C23C 16/45544

(57) ABSTRACT

A substrate processing apparatus includes: a substrate processor including a plurality of end devices and performing substrate processing on a substrate by using the end devices; and a controller controlling the substrate processing in the substrate processor, wherein the controller includes a higher-level control unit and a plurality of control boards that are lower-level control units connected to the higher-level control unit via a network, and the control boards send or receive a control signal to or from the end devices and include a clock generator that performs time measurement, and wherein the controller includes a time deviation corrector that transmits a clock signal for a certain period of time from the higher-level control unit to the control boards and that corrects a deviation in actual operation time caused by the clock generator based on the clock signal from the higher-level control unit, in each of the control boards.

### CROSS-REFERENCE TO RELATED APPLICATION

This application is a bypass continuation application of International Patent Application No. PCT/JP2023/019724 having an international filing date of May 26, 2023 and designating the United States, the international application being based upon and claiming the benefit of priority from Japanese Patent Application No. 2022-093974, filed on Jun. 9, 2022, the entire contents of which are incorporated herein by reference.

### TECHNICAL FIELD

The present disclosure relates to a substrate processing apparatus, a control system, and a control method.

### BACKGROUND

For example, in a manufacturing process of semiconductor devices, various types of processing such as film formation, etching, and heat treatment are performed on a semiconductor wafer, which serves as a substrate. In a processing apparatus that performs these types of processing, particularly in a processing apparatus that performs an ALD (Atomic Layer Deposition) process for film formation, there are multiple end devices that require high-speed control, such as high-speed opening/closing valves and automatic pressure control valves for ALD. As a technique to realize the high-speed control of such end devices, Patent Document 1 discloses a technique where multiple high-speed control boards, specialized for the high-speed control of the end devices, are connected via a network to a controller that controls an apparatus, and the end devices are controlled based on a processing recipe given from the controller.

### PRIOR ART DOCUMENTS

### Patent Documents

Patent Document 1: Japanese laid-open publication No. 2013-151723

### SUMMARY

According to one embodiment of the present disclosure, there is provided a substrate processing apparatus for processing a substrate, the substrate processing apparatus including: a substrate processor including a plurality of end devices and configured to perform substrate processing on the substrate by using the plurality of end devices; and a controller configured to control the substrate processing in the substrate processor, wherein the controller includes a higher-level control unit and a plurality of control boards that are lower-level control units and are connected to the higher-level control unit via a network, and the plurality of control boards send or receive a control signal to or from the plurality of end devices and include a clock generator that performs time measurement, and wherein the controller further includes a time deviation corrector that transmits a clock signal for a certain period of time from the higher-level control unit to the plurality of control boards and that corrects a deviation in actual operation time caused by the clock generator based on the clock signal from the higher-level control unit, in each of the plurality of control boards.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating an example of a substrate processing apparatus according to one embodiment.

FIG. 2 is a block diagram illustrating a schematic configuration of an overall control system including a controller of the substrate processing apparatus according to one embodiment.

FIG. 3 is a block diagram illustrating a time deviation corrector provided in the controller.

FIG. 4 is a flowchart illustrating a control operation performed by the controller.

FIG. 5 is a block diagram illustrating a schematic configuration of major components of the controller.

FIG. 6 is a block diagram illustrating a controller state when a local recipe is downloaded.

FIG. 7 is a block diagram illustrating a controller state when the local recipe starts.

FIG. 8 is a block diagram illustrating a controller state when controlling an end device and executing substrate processing based on the local recipe.

FIG. 9 is a block diagram illustrating a controller state when a time deviation occurs in a high-speed control board.

FIG. 10 is a block diagram illustrating a controller state when correcting a deviation in actual operation time in the high-speed control board based on a clock signal from a higher-level control unit.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments are described with reference to the accompanying drawings.

### <Substrate Processing Apparatus>

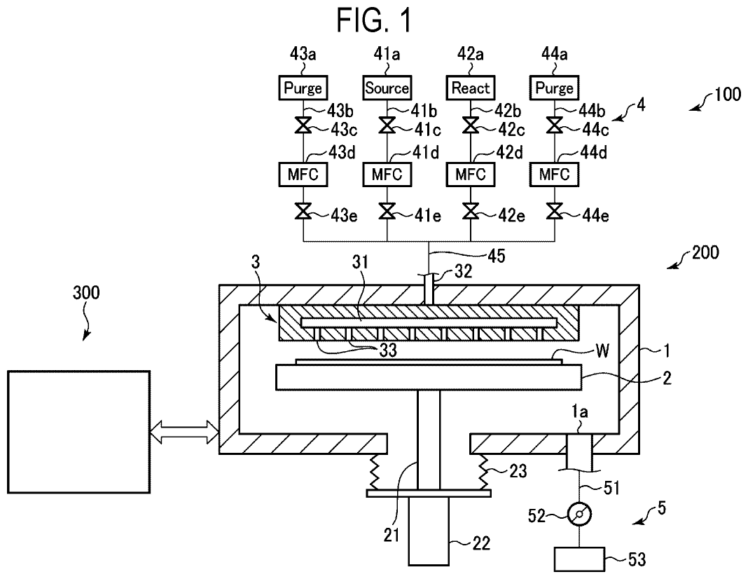

FIG. 1 is a cross-sectional view schematically illustrating an example of a substrate processing apparatus according to one embodiment.

In the present embodiment, a case where a substrate processing apparatus 100 is a film forming apparatus that forms a film on a substrate by ALD using a raw material gas and a reactant gas is illustrated. The substrate processing apparatus 100 includes a substrate processor 200 and a controller 300.

### [Substrate Processor]

The substrate processor 200 includes a processing container 1, a stage 2, a shower head 3, a gas supplier 4, and an exhauster 5.

The processing container 1 is made of a metal such as aluminum and has an approximately cylindrical shape. A loading/unloading port (not illustrated) for loading or unloading a substrate W is formed at a sidewall of the processing container 1, and the loading/unloading port may be opened or closed by a gate valve (not illustrated). Further, an exhaust port 1a is provided at a bottom of the processing container 1.

The stage 2 takes a shape of a disk with a size corresponding to the substrate W, and is provided horizontally inside the processing container 1 and supported by a support member 21. The stage 2 is made of a ceramic material such as aluminum nitride (AlN) or a metallic material such as aluminum or nickel-based alloy, and includes a heater (not illustrated) embedded therein for heating the substrate W. The heater is raised in temperature upon receiving power supplied from a heater power supply (not illustrated). A temperature sensor (not illustrated) is provided near an upper surface of the stage 2, and a temperature of the substrate W is controlled by controlling an output of the heater by the temperature sensor.

The support member 21 passes through a hole formed at a bottom wall of the processing container 1 from a center of a bottom surface of the stage 2 to extend downward from the processing container 1 and is connected at a lower end thereof to a lift 22. This allows the stage 2 to be raised or lowered by the lift 22 via the support member 21. During an ALD process, a pressure near the substrate W may be controlled by raising or lowering the stage 2 by the lift 22.

A bellows 23 is provided between the lift 22 and the bottom wall of the processing container 1 to separate an internal atmosphere of the processing container 1 from outside air. The bellows 23 expands or contracts according to a raising or lowering operation of the stage 2.

The shower head 3 is provided at a top of the processing container 1 to face the stage 2 and functions as a gas discharger that discharges a process gas into the processing container 1 in a shower-like manner. The shower head 3 is made, for example, of a metallic material, and has a substantially the same diameter as the stage 2. A gas diffusion space 31 for diffusion of gases is formed in an interior of the shower head 3, and a gas introduction pipe 32 is connected from above to the gas diffusion space 31. Multiple gas discharge holes 33 are formed at a bottom wall of the shower head 3 and are configured to allow gases supplied from the gas introduction pipe 32 to the gas diffusion space 31 to be discharged into the processing container 1 through the gas discharge holes 33.

The gas supplier 4 is for supplying gases such as a raw material gas, reactant gas, and purge gas used in ALD film formation to the processing container 1 via the shower head 3. The raw material gas is a compound gas containing a metal component of a film to be formed, and the reactant gas is a gas for reacting with the raw material gas to form the film. Further, the purge gas is for purging any remaining gases in the processing container 1, and an inert gas such as a N₂ gas or noble gas is used as the purge gas.

The gas supplier 4 includes a raw material gas source 41a for supplying the raw material gas, a reactant gas source 42a for supplying the reactant gas, and a first purge gas source 43a and a second purge gas source 44a for supplying the purge gas.

A raw material gas supply pipe 41b, a reactant gas supply pipe 42b, a first purge gas supply pipe 43b, and a second purge gas supply pipe 44b are connected to the raw material gas source 41a, the reactant gas source 42a, the first purge gas source 43a, and the second purge gas source 44a, respectively. The raw material gas supply pipe 41b is provided, in sequence from the raw material gas source 41a, with a preceding-side valve 41c, a flow-rate controller 41d, and a latter-side valve 41e. The reactant gas supply pipe 42b is provided, in sequence from the reactant gas source 42a, with a preceding-side valve 42c, a flow-rate controller 42d, and a latter-side valve 42e. The first purge gas supply pipe 43b is provided, in sequence from the first purge gas source 43a, with a preceding-side valve 43c, a flow-rate controller 43d, and a latter-side valve 43e. The second purge gas supply pipe 44b is provided, in sequence from the second purge gas source 44a, with a preceding-side valve 44c, a flow-rate controller 44d, and a latter-side valve 44e.

The raw material gas supply pipe 41b, the reactant gas supply pipe 42b, the first purge gas supply pipe 43b, and the second purge gas supply pipe 44b all merge into a common pipe 45, and the common pipe 45 is connected to the gas introduction pipe 32.

The first purge gas supply pipe 43b and the second purge gas supply pipe 44b are provided on the raw material gas supply pipe 41b side and on the reactant gas supply pipe 42b side respectively, and the purge gas flowing through these pipes also functions as a carrier gas for each of the raw material gas and the reactant gas.

The preceding-side valves 41c, 42c, 43c and 44c are regular opening/closing valves, and the latter-side valves 41e, 42e, 43e and 44e are high-speed opening/closing valves for ALD. For example, mass flow controllers are used as the flow-rate controllers 41d, 42d, 43d and 44d.

The exhauster 5 exhausts an interior of the processing container 1 to reduce an internal pressure of the processing container 1. The exhauster 5 includes an exhaust pipe 51, an automatic pressure control valve (APC) 52, and a vacuum pump 53. The exhaust pipe 51 is connected to the exhaust port 1a. The automatic pressure control valve (APC) 52 and the vacuum pump 53 are provided at the exhaust pipe 51. As the automatic pressure control valve (APC) 52, a valve that controls a conductance in the exhaust pipe 51 by adjusting an opening degree thereof may be used. The opening degree of the pressure control valve (APC) (52) is controlled so that a pressure value from a pressure sensor (not illustrated) that detects the internal pressure of the processing container 1 reaches a desired value.

In the substrate processor 200, the following process is executed under control of the controller 300.

First, the substrate W is loaded into the processing container 1 and is placed onto the stage 2, the interior of the processing container 1 is maintained in a predetermined reduced pressure state, and a temperature of the stage 2 is controlled to a set temperature by using the heater. In this state, the purge gas is supplied from the gas supplier 4 into the processing container 1 through the shower head 3 to purge the interior of the processing container 1.

Thereafter, the high-speed opening/closing valves 41e to 44e for ALD are opened or closed at high speeds to repeatedly perform supply of the raw material gas into the processing container 1, purging of any remaining gases inside the processing container 1, supply of the reactant gas into the processing container 1, and the purging of any remaining gases inside the processing container 1 at high speeds. By this, an ALD process is performed in which film forming by adsorption of the raw material gas onto the substrate W and reaction between the raw material gas and the reactant gas is repeated, resulting in formation of a film with a set film thickness on the substrate W.

During this ALD process, high-speed pressure control is performed by the automatic pressure control valve (APC) 52 and high-speed raising or lowering of the stage 2 is performed by the lift 22, at each step of the ALD process.

### [Overall Control System Including Controller of Substrate Processing Apparatus]

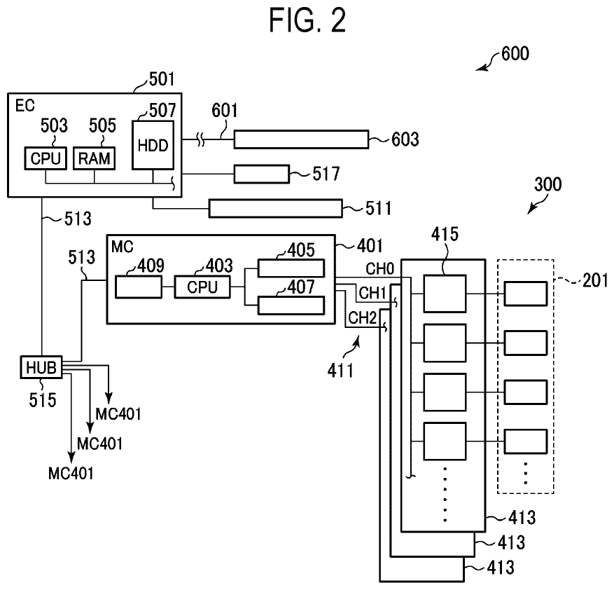

FIG. 2 is a block diagram illustrating a schematic configuration of an overall control system including the controller 300. The controller 300 is for controlling each component constituting the substrate processor 200 and executing processing in the substrate processing apparatus 100. The controller 300 is configured as a part of an overall control system 600 that controls the entire substrate processing system including the substrate processing apparatus 100.

As illustrated in FIG. 2, the overall control system 600 includes an equipment controller (EC) 501, which is a central unit for controlling the entire substrate processing system, and a plurality of module controllers (MCs) 401 for controlling each lower-level apparatus (module) that constitutes the substrate processing system.

The EC 501 functions as a common higher-level controller for controlling a plurality of apparatuses of the substrate processing system, and the substrate processing apparatus 100 is included as one of the plurality of apparatuses (modules). Other apparatuses besides the substrate processing apparatus 100 may be, for example, a load lock chamber, a loader unit, and others. Although the plurality of MCs 401 are provided to correspond to the plurality of apparatuses (modules), FIG. 2 illustrates only the MC 401 of the substrate processing apparatus 100, with others omitted.

The controller 300 includes the EC 501, the MC 401 corresponding to the substrate processing apparatus 100, and a plurality of high-speed control boards 413 provided as lower-level components. The high-speed control boards 413 are configured as I/O modules that control a plurality of end devices 201, which are high-speed control target devices. The MC 401 and the EC 501 are positioned as higher-level control units from the perspective of the high-speed control boards 413.

The EC 501 includes a central processing unit (CPU) 503, a RAM 505 as a volatile memory, and a hard disk drive 507 as a storage. The EC 501 is connected to each MC 401 via a network 513. The network 513 may be appropriately an ultra-high-speed field network system such as Ether-CAT (hereinafter referred to as E-CAT). The network 513 includes a switching hub (HUB) 515. The switching hub 515 performs switching of the MC 401 as a connection location of the EC 501 according to control signals from the EC 501.

Further, the EC 501 is connected via a network 601 to a host computer 603, which serves as a manufacturing execution system (MES) that manages an entire manufacturing process of a factory where the substrate processing system is installed.

Further, the EC 501 is connected to a user interface 511. The user interface 511 includes a keyboard, by which a process manager performs, e.g., input of commands for managing the substrate processing system, a display for visualizing and displaying an operational status of the substrate processing system, mechanical switches, and others.

The EC 501 is capable of recording information on a computer-readable storage medium 517 and reading information from the storage medium 517.

In the EC 501, the CPU 503 reads a program including a processing recipe for the substrate W, as specified by the user or others through the user interface 511, from the hard disk drive 507 or the storage medium 517. Then, the EC 501 is configured to send the program including the processing recipe to the plurality of MCs 401. As described above, one of the plurality of MCs 401 corresponds to the controller 300 of the substrate processing apparatus 100.

Among the plurality of MCs 401, the MC 401, which corresponds to the film forming apparatus 100 and is included in the controller 300, includes a CPU 403, a volatile memory 405 such as RAM, a nonvolatile memory 407 serving as an I/O information storage, and an I/O controller 409.

The nonvolatile memory 407 stores various types of historical information regarding the substrate processing apparatus 100. Further, the nonvolatile memory 407 also functions as an I/O information storage where, as described later, various types of I/O information exchanged between the MC 401 and the plurality of end devices 201, which are the high-speed control target devices, may be written and stored therein as needed.

Examples of the end devices 201 may include the high-speed opening/closing valves 41e to 44e and flow-rate controllers 41d to 44e in the gas supplier 4, the automatic pressure control valve (APC) 52 in the exhauster 5, the lift 22, the heater power supply, various sensors, and others.

The I/O controller 409 of the MC 401 sends various control signals to the high-speed control boards 413, or receives signals such as status information regarding each end device 201 from the high-speed control boards 413. The control of each end device 201 by the MC 401 is performed via the high-speed control boards 413. Each high-speed control board 413 is configured as the I/O module as described above, performing the transmission of control signals to each end device 201 and the transmission of input signals from each end device 201. The high-speed control board 413 and each end device 201 are connected to each other with digital/analog signals. The MC 401 is connected to the plurality of high-speed control boards 413 via the network 411. The network may be appropriately an ultra-high-speed field network E-CAT to perform E-CAT communication. The network 411 connected to the MC 401 includes a plurality of channels such as CH0, CH1 and CH2.

The plurality of high-speed control boards 413, which are lower-level control units, each have a plurality of I/O boards 415 connected to the respective end devices 201 each constituting the film forming apparatus 100. These I/O boards 415 operate based on control of the MC 401. Control of input/output of digital signals, analog signals, and serial signals in the high-speed control board 413 is performed by these I/O boards 415.

Input/output information managed by the I/O boards 415 includes digital input information (DI), digital output information (DO), and analog input information (AI). DI relates to digital information input from the respective lower-level end devices 201 to the higher-level MC 401. DO relates to digital information output from the higher-level MC 401 to the respective lower-level end devices 201. AI relates to analog information input from the respective end devices to the MC 401.

DI and AI include, for example, information regarding the status of the respective end devices 201. DO includes, for example, commands for setting values related to process conditions for the respective end devices. That is, DI and AI handle, in the embodiment, device monitoring, while DO handles, in the embodiment, device operation.

DI, DO, and AI are each assigned an I/O address corresponding to content thereof. Each I/O address contains, for example, 16-bit (0 to 15) digital information or analog information. The analog information is represented, for example, in hexadecimal from 0 to FFF. Further, each I/O address is assigned an address number. Furthermore, the I/O boards 415 are assigned node numbers starting from 1. Then, the plurality of channels are assigned numbers such as CH0, CH1, and CH2, as described above. Therefore, the I/O addresses of DI, DO, and AI may be specified by using three types of parameters: the channel number, the node number, and the I/O address number.

Classification of end devices 201 controlled by each high-speed control board 413 is arbitrary. The end devices 201 connected to each high-speed control board 413 may either be of the same type or a mixture of different types. An example of the former may be classifying each of the plurality of high-speed control boards 413 to different functions such as for the control of the valves in the gas supplier 4, for the automatic pressure control valve 52, and for the lift 22, etc. Further, an example of the latter may be connecting multiple types of end devices 201, such as the valves in the gas supplier and the automatic pressure control valve, to a single high-speed control board 413, and distributing the control of the plurality of valves in the gas supplier across the plurality of high-speed control boards 413.

As described above, the processing recipe for processing the substrate W in the substrate processing apparatus 100 is sent from the EC 501 to the MC 401 corresponding to the substrate processing apparatus 100. The processing recipe sent to the MC 401 is used to control the plurality of end devices 201. The processing recipe is downloaded from the MC 401 to each high-speed control board 413 via the network 411 as a local recipe (program) corresponding to each high-speed control board 413. Then, the high-speed control board 413 controls the corresponding end devices 201 based on the downloaded local recipe.

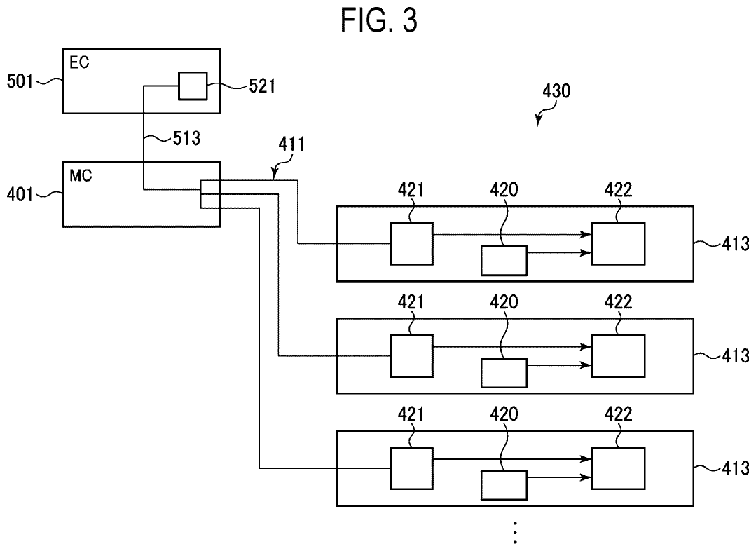

As illustrated in FIG. 3, each high-speed control board 413 is equipped with a clock generator 420 that performs time measurement. During execution of the local recipe, operation time, monitoring time, and others are determined by fixed calculation formulas in the program based on a clock generated by the clock generator 420. The clock generator 420 includes an element such as a crystal oscillator for generating clock signals, and generates clock signals from this element.

The controller 300 includes a time deviation corrector that sends a clock signal for a certain period of time from a higher-level control unit to each high-speed control board 413, which is a lower-level control unit, and that corrects a deviation in actual operation time in each high-speed control board 413 based on the clock signal from the higher-level control unit.

In other words, as illustrated in FIG. 3, the time deviation corrector 430 includes a signal transmitter 521 provided in the EC 501, which is the higher-level control unit, a signal receiver 421 provided in each high-speed control board 413, and a corrector 422 provided in each high-speed control board 413. The signal transmitter 521 transmits a clock signal generated for a certain period of time, for example, by a crystal oscillator to the high-speed control board 413 via the networks 513 and 411, for example, E-CAT communication. The signal receiver 421 receives the clock signal from the signal transmitter 521. The corrector 422 compares a cycle of the signal received by the signal receiver 421 with a signal cycle of the clock generator 420 to correct a time deviation caused by the clock generator 420 in real time. The signal transmission from the signal transmitter 521 may be performed multiple times at regular intervals, or may be continued at regular intervals at least during a period when substrate processing is being performed. Further, the signal transmission may be performed continuously at regular intervals.

For a specific example, the signal transmitter 521 may transmit a clock signal with a constant period of time, such as 1 second, generated by the crystal oscillator, at regular intervals such as once every 1 minute, and this clock signal is received by the signal receiver 421 of each high-speed control board 413. Then, the corrector 422 in each high-speed control board 413 compares, for example, the number of oscillations per unit time of the crystal oscillator received by the signal receiver 421 with the number of oscillations per unit time of the crystal oscillator of the clock generator 420, and corrects a time deviation based on this comparison.

### <Control Operation>

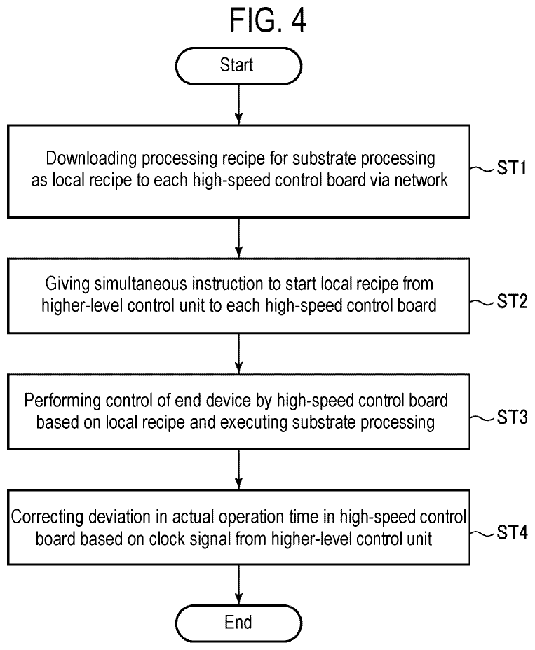

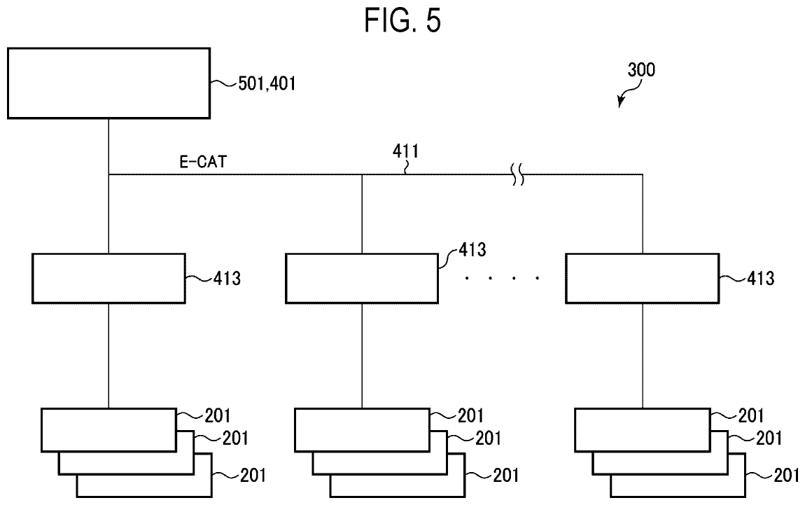

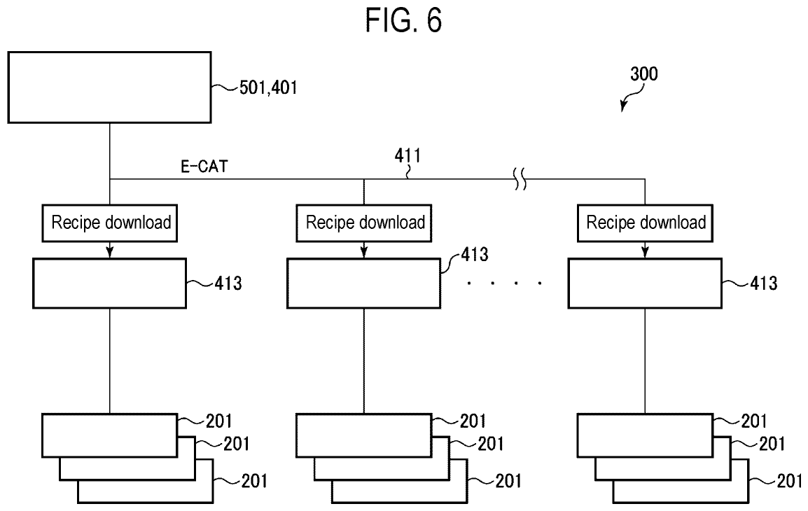

Next, a control operation in the substrate processing apparatus 100 configured as described above is described with reference to FIGS. 4 to 9. FIG. 4 is a flowchart illustrating a control operation of the controller 300 of the substrate processing apparatus 100, FIG. 5 is a block diagram illustrating a schematic configuration of major components of the controller 300, and FIGS. 6 to 10 are block diagrams illustrating states of the controller 300 to illustrate the control operation.

In the present embodiment, the ALD process as described above is performed as an example of the substrate processing. The ALD process is performed by controlling the plurality of end devices 201 of the substrate processor 200 by the controller 300 based on the processing recipe.

First, in the controller 300 configured as illustrated in FIG. 5, the processing recipe for performing the processing of the substrate W sent from the EC 501 to the MC 401 corresponding to the substrate processing apparatus 100 is downloaded as a local recipe to each high-speed control board 413 via the network 411 (Step ST1, FIG. 6). As described above, the EC 501 and the MC 401 function as higher-level control units, and the high-speed control board 413s function as lower-level control units. Further, the network 411 may be appropriately, for example, E-CAT.

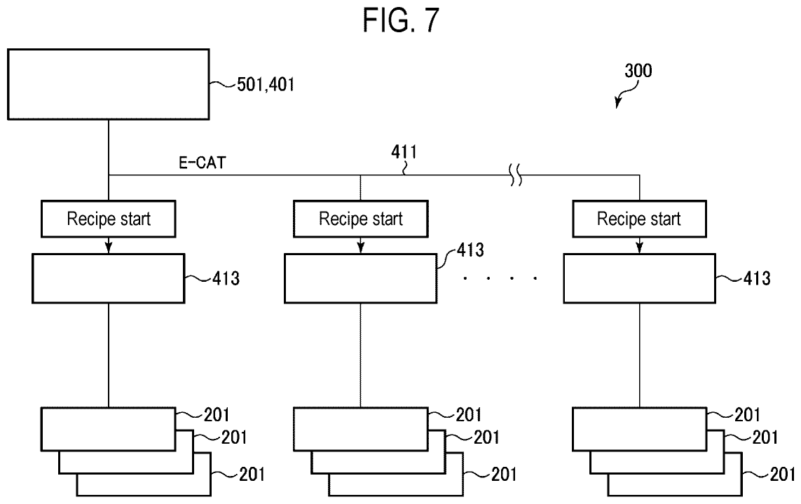

Next, an instruction to start the local recipe is simultaneously given from the higher-level control unit, i.e., the MC 401 to each high-speed control board 413 (Step ST2, FIG. 7).

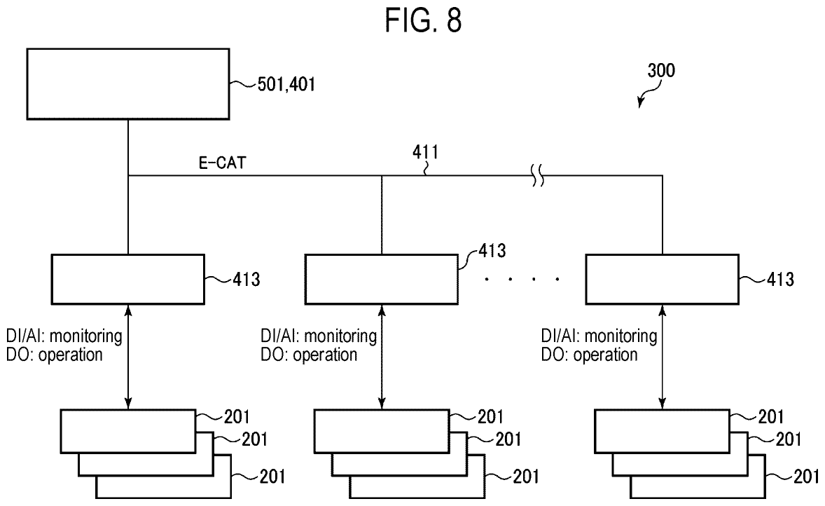

Next, based on the local recipe, the high-speed control board 413 (I/O board 415) performs the control of the end devices (high-speed control target devices) 201 such as device operation by DO and device monitoring by DI/AI, and executes the substrate processing such as the ALD process as described above (Step ST3, FIG. 8).

However, when high-speed control is required for the substrate processing, such as in the ALD process, a control cycle becomes shorter than a cycle of the network, for example, E-CAT. Therefore, control time is determined based on the clock generator 420 provided in each high-speed control board 413.

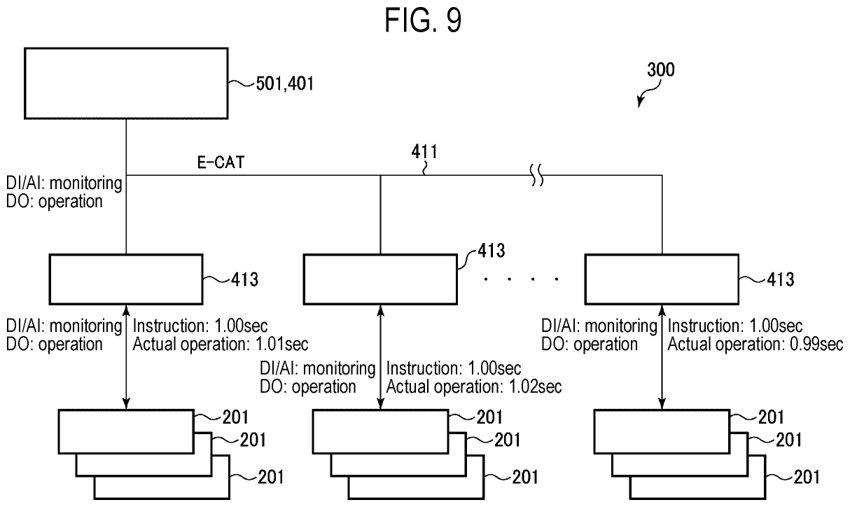

However, when determining the operation time and monitoring time in the local recipe based on the clock generator 420, factors, such as the surrounding environment, individual differences in the crystal oscillator of the clock generator 420, deterioration over time, and others, may cause relative time deviations among the plurality of high-speed control boards 413, or an absolute time deviation, such as 1 minute not being equal to 1 minute. For example, as illustrated in FIG. 9, even if an instruction from the higher-level control system is 1 second, the actual operation time may deviate in the high-speed control board 413.

Even if such a time deviation is small for each occurrence, the deviation may accumulate, having a significant effect if the recipe time is extended due to factors such as a thicker film. For example, an interlinking of operations among the plurality of end devices that is needed to operate in conjunction with each other may not be maintained.

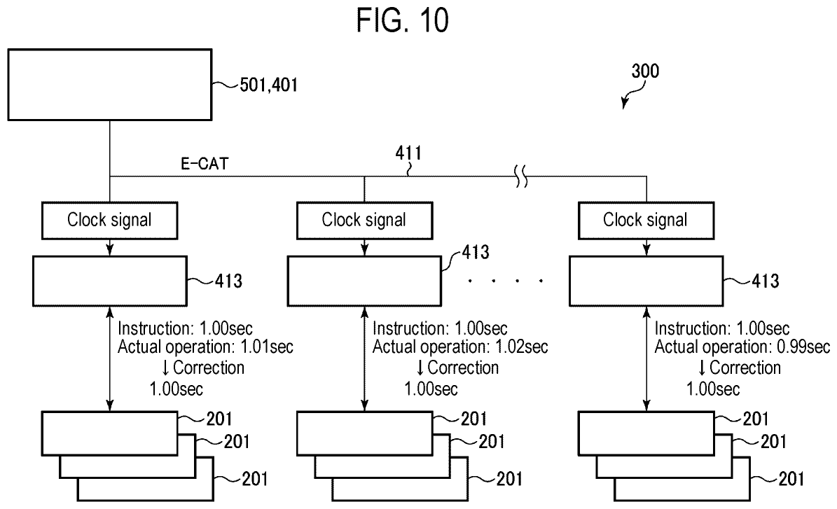

Therefore, in the present embodiment, a deviation in actual operation time in the high-speed control board 413 is corrected based on a clock signal from the higher-level control system, which is less susceptible to factors, such as the surrounding environment, individual differences, deterioration over time, and others (Step ST4, FIG. 10). This deviation in actual operation time is corrected by the time deviation corrector 430 as described above. Specifically, in the time deviation corrector 430, the signal transmitter 521 of the higher-level control system, i.e., the EC 501, transmits the clock signal generated, for example, by the crystal oscillator to the high-speed control board 413 at regular intervals via the networks 513 and 411 such as E-CAT communication. Then, the signal is received by the signal receiver 421 of the high-speed control board 413, and the corrector 422 compares the cycle of the signal received by the signal receiver 421 with the signal cycle of the clock generator 420 to correct the time deviation based on the clock generator 420 in real time. This allows for the prevention of relative time deviations among the high-speed control boards 413 as well as an absolute time deviation.

For example, as illustrated in FIG. 10, a time deviation on the basis of an instructed time of 1 second in each high-speed control board 413 may be corrected by the corrector 422 based on, for example, clock signals generated every 1 minute from the higher-level control system, i.e., the EC 501, thereby eliminating an absolute time deviation.

Further, there is a possibility of control time deviations occurring among a plurality of apparatuses including the substrate processing apparatus 100 constituting the substrate processing system. However, by transmitting the clock signals from the signal transmitter 521 of the EC 501 to a plurality of high-speed control boards of each apparatus for correction, the time deviations among the apparatuses may also be eliminated.

### Other Applications

Although the embodiments have been described above, the embodiments disclosed herein should be considered to be exemplary and not restrictive in all respects. The above embodiments may be omitted, replaced, or modified in various ways without departing from the scope and spirit of the appended claims.

For example, in the above embodiment, the description is provided using an apparatus for performing ALD film formation as an example of a substrate processing apparatus. However, it is not limited to apparatuses that perform ALD film formation as long as substrate processing is controlled by issuing commands from a higher-level control unit to each end device via a plurality of control boards.

Further, the configuration of the controller is not limited to that illustrated in FIG. 2 as long as the controller controls each end device from the higher-level control system via a plurality of control boards.

Further, the substrate is not particularly limited, and, for example, a semiconductor wafer, a glass substrate used for a flat panel display (FPD), a ceramic substrate, and others may be used as the substrate.

According to the present disclosure, a substrate processing apparatus, a control system, and a control method are provided, in which time deviations among control boards or an absolute time deviation is unlikely to occur.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus for processing a substrate, the substrate processing apparatus comprising:
a substrate processor including a plurality of end devices and configured to perform substrate processing on the substrate by using the plurality of end devices; and
a controller configured to control the substrate processing in the substrate processor,
wherein the controller includes a higher-level control unit and a plurality of control boards that are lower-level control units and are connected to the higher-level control unit via a network, and the plurality of control boards send or receive a control signal to or from the plurality of end devices and each of the plurality of control boards include a clock generator that performs time measurement, and
wherein the controller further includes a time deviation corrector that transmits a clock signal for a certain period of time from the higher-level control unit to the plurality of control boards and that corrects a deviation in actual operation time caused by the clock generator based on the clock signal from the higher-level control unit, in each of the plurality of control boards.

2. The substrate processing apparatus of claim 1, wherein the time deviation corrector includes:
a signal transmitter provided in the higher-level control unit and configured to transmit the clock signal at a certain interval to the plurality of control boards via the network;
a signal receiver provided in the plurality of control boards and configured to receive the clock signal from the signal transmitter; and
a corrector provided in the plurality of control boards and configured to compare a cycle of the clock signal received by the signal receiver with a signal cycle of the clock generator and correct a time deviation caused by the clock generator.

3. The substrate processing apparatus of claim 2, wherein the signal transmitter transmits the clock signal at the certain interval at least during a period when the substrate processing is being performed.

4. The substrate processing apparatus of claim 2, wherein the clock generator generates a clock signal by using a crystal oscillator, and the clock signal from the signal transmitter is transmitted by a crystal oscillator, and
wherein the corrector compares a number of oscillations per unit time of the crystal oscillator received by the signal receiver with a number of oscillations per unit time of the crystal oscillator of the clock generator and corrects the time deviation based on the comparison.

5. The substrate processing apparatus of claim 1, wherein the plurality of control boards are I/O modules that control input and output of digital signals and analog signals to and from the plurality of end devices and perform high-speed control.

6. The substrate processing apparatus of claim 5, wherein the higher-level control unit has a processing recipe to perform the substrate processing, and the processing recipe is downloaded as a local recipe to each of the plurality of control boards.

7. The substrate processing apparatus of claim 1, wherein the substrate processor performs ALD film formation on the substrate.

8. A control system for controlling a substrate processing apparatus that performs substrate processing on a substrate, the control system comprising:
a higher-level control unit; and
a plurality of control boards that are lower-level control units and are connected to the higher-level control unit via a network,
wherein the plurality of control boards send or receive a control signal to or from a plurality of end devices that are components of the substrate processing apparatus to perform the substrate processing on the substrate, and each of the plurality of control boards include a clock generator that performs time measurement, and
wherein the control system further comprises a time deviation corrector that transmits a clock signal for a certain period of time from the higher-level control unit to the plurality of control boards and that corrects a deviation in actual operation time caused by the clock generator based on the clock signal from the higher-level control unit, in each of the plurality of control boards.

9. The control system of claim 8, wherein the time deviation corrector includes:
a signal transmitter provided in the higher-level control unit and configured to transmit the clock signal at a certain interval to the plurality of control boards via the network;
a signal receiver provided in the plurality of control boards and configured to receive the clock signal from the signal transmitter; and
a corrector provided in the plurality of control boards and configured to compare a cycle of the clock signal received by the signal receiver with a signal cycle of the clock generator and correct a time deviation caused by the clock generator.

10. The control system of claim 9, wherein the signal transmitter transmits the clock signal at the certain interval at least during a period when the substrate processing is being performed.

11. The control system of claim 9, wherein the clock generator generates a clock signal by using a crystal oscillator, and the clock signal from the signal transmitter is transmitted by a crystal oscillator, and
wherein the corrector compares a number of oscillations per unit time of the crystal oscillator received by the signal receiver with a number of oscillations per unit time of the crystal oscillator of the clock generator and corrects the time deviation based on the comparison.

12. The control system of claim 8, wherein the plurality of control boards are I/O modules that control input and output of digital signals and analog signals to and from the plurality of end devices and perform high-speed control.

13. The control system of claim 12, wherein the higher-level control unit has a processing recipe to perform the substrate processing, and the processing recipe is downloaded as a local recipe to each of the plurality of control boards.

14. The control system of claim 8, wherein the higher-level control unit includes an apparatus controller that controls the substrate processing apparatus and a facility controller that controls an entire substrate processing system including a plurality of apparatuses including the substrate processing apparatus, and the higher-level control unit transmits the clock signal from the facility controller to the plurality of control boards through the apparatus controller.

15. The control system of claim 14, wherein the substrate processing system includes a plurality of apparatus controllers corresponding to the plurality of apparatuses including the substrate processing apparatus, and the plurality of control boards are connected to the plurality of apparatus controllers, respectively, and the substrate processing system transmits the clock signal from the facility controller to the plurality of control boards in the plurality of apparatuses through the plurality of apparatus controllers.

16. A control method of controlling a substrate processing apparatus that performs substrate processing on a substrate, the control method comprising:
using a control system including a higher-level control unit and a plurality of control boards that are lower-level control units and are connected to the higher-level control unit via a network, and performing the substrate processing by sending or receiving a control signal between the plurality of control boards and a plurality of end devices that are components of the substrate processing apparatus to perform the substrate processing on the substrate; and
transmitting a clock signal for a certain period of time from the higher-level control unit to the plurality of control boards, and correcting a deviation in actual operation time caused by a clock generator, provided in each of the plurality of control boards to perform time measurement, based on the clock signal from the higher-level control unit, in each of the plurality of control boards.

17. The control method of claim 16, wherein the clock signal is transmitted at a certain interval at least during a period when the substrate processing is being performed.

18. The control method of claim 16, wherein the clock signal from the higher-level control unit and a clock signal from the clock generator provided in the plurality of control boards are both transmitted by crystal oscillators, and
wherein a number of oscillations per unit time of the clock signal from the higher-level control unit and a number of oscillations per unit time of the clock signal from the clock generator are compared, and a time deviation is corrected based on the comparison.

19. The control method of claim 16, wherein the plurality of control boards are I/O modules that control input and output of digital signals and analog signals to and from the plurality of end devices and perform high-speed control.

20. The control method of claim 19, wherein the higher-level control unit has a processing recipe to perform the substrate processing, and the substrate processing is performed by downloading the processing recipe as a local recipe to each of the plurality of control boards.
